(19) United States
(12) Patent Application Publication
(10) Pub. No.: US 2026/0362587 A1
(43) Pub. Date: Nov. 12, 2026

(54) RECESSED PATTERNED CORE VIA ARRAY AND METHOD OF MANUFACTURE

(71) Applicant: Astera Labs, Inc., San Jose, CA (US)

(72) Inventors: Abhinaya Easwari MOHAN, San Jose, CA (US); Zengji ZHAO, Sunnyvale, CA (US); Tony Yiqi TANG, Allen, TX (US)

(21) Appl. No.: 19/346,541

(22) Filed: Sep. 30, 2025

Related U.S. Application Data
(60) Provisional application No. 63/803,460, filed on May 9, 2025.

(51) Int. Cl. H05K 1/02; H05K 1/11; H05K 3/42

(52) U.S. Cl. CPC H05K 1/0228; H05K 1/112; H05K 3/429

(57) ABSTRACT

An electronic system having a mounting substrate with a plurality of layers. The mounting substrate includes differential pair traces with a signal line and an inverted line where the inverted line carries an inverted version of the signal line. The differential pair traces include transition vias positioned approximately halfway between a start pad and an end pad and the transition vias extending between internal layers to reduce the line impedance of the differential pair.

### CROSS-REFERENCE TO RELATED APPLICATIONS

This application claims the benefit of U.S. Provisional Patent Application Ser. No. 63/803,460 filed May 9, 2025, the entire contents of the aforementioned are hereby incorporated by reference as if fully set forth herein, under 35 U.S.C. § 120.

### TECHNICAL FIELD

Embodiments relate generally to electrical structures for improving performance in electronic circuit packages and more specifically, to package substrates with a recessed patterned core via array to improve crosstalk performance and methods of manufacture.

### BACKGROUND OF THE INVENTION

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

The development of electronic circuitry and products has been influenced by the physical and electrical properties of the materials and structures used to form the electronic components and circuitry. These products provide increased functionality and features for the end users.

Electronic components must be electrically connected to other electronic components and systems for proper operation. Electronic components can be mounted on multilayer circuit boards and electrically coupled with power distribution networks. Electronic systems can control power and signal traffic over elements such as vertical vias, signal traces, power traces, and ground traces. The size, shape, power levels, and electrical parameters of the electronic components can have an impact on the operational performance.

The electrical properties of the electronic components and power distribution components can influence the electrical operating properties of the circuit. Some systems can exhibit instability, oscillation effects, signal leakage, reflection, frequency change, and other unintended effects. Reducing the effect of such electrical configurations can reduce unwanted effects and increase the overall efficiency and performance of the circuit operation.

### BRIEF DESCRIPTION OF DRAWINGS

The present invention is illustrated by way of example, and not by way of limitation, in the figures of the accompanying drawings and in which like reference numerals refer to similar elements and in which:

FIG. 1 depicts an example embodiment of an electronic system,

FIG. 2 depicts an example embodiment of a mounting substrate of the electronic system,

FIG. 3 depicts an example embodiment of the mounting substrate.

FIG. 4 depicts an example embodiment of a mounting substrate of a ball grid array package,

FIG. 5 depicts another example embodiment of the mounting substrate,

FIGS. 6A and 6B depict example embodiments of differential pairs on a mounting substrate,

FIG. 6A depicts an example embodiment of the mounting substrate in a tightly coupled configuration,

FIG. 6B depicts an example embodiment of the differential pairs on the mounting substrate of a ball grid array package,

FIGS. 7A and 7B depict example embodiments of differential pairs on a mounting substrate,

FIG. 7A depicts an example embodiment of the mounting substrate in a loosely coupled configuration,

FIG. 7B depicts an example embodiment of the differential pairs on the mounting substrate of a ball grid array package,

FIGS. 8A, 8B, and 8C depict example embodiments of a transition via,

FIG. 8A depicts an example embodiment of a top view of the transition via on the mounting substrate,

FIG. 8B depicts an example embodiment of a side view of the transition via,

FIG. 8C depicts an example embodiment of the transition vias,

FIGS. 9A, 9B, and 9C depict example embodiments of a differential pair transition via,

FIG. 9A depicts an example embodiment of a differential pair with transition vias,

FIG. 9B depicts an example embodiment of a side view of a differential pair with vias,

FIG. 9C depicts an example embodiment of a side view of differential pairs with the transition vias,

FIG. 10 depicts an example of a receiver-receiver return loss graph for an embodiment of the electronic system,

FIG. 11 depicts an example of a receiver-receiver return loss graph for an embodiment of the electronic system,

FIG. 12 depicts an example of a receiver-receiver return loss graph for an embodiment of the electronic system,

FIG. 13 depicts an example of a receiver return loss graph for an embodiment of the electronic system,

FIG. 14 depicts an example of a receiver return loss graph for an embodiment of the electronic system,

FIG. 15 depicts an example of a time domain reflectometer impedance graph for an embodiment of the electronic system,

FIG. 16 depicts an example of a time domain reflectometer impedance graph for an embodiment of the electronic system, and

FIG. 17 depicts an example of a manufacturing process flow for the electronic system in an embodiment.

### DETAILED DESCRIPTION OF THE INVENTION

In the following detailed description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

Embodiments are described herein according to the following outline:
1.0. Overview
2.0. System Overview
3.0. Performance Analysis
4.0. Functional Overview
5.0. Example Embodiments
6.0. Extensions and Alternatives

### 1.0. Overview

Approaches, techniques, and mechanisms are disclosed for manufacturing and use of the electronic systems discussed herein including electronic systems with multi-layer components and substrates. The electronic systems can improve performance and reduce electrical operating factors between conductive elements by creating directional current flow structures to compensate for inductance and capacitance factors between and around elements in the multi-layer substrates. By reducing loop inductance between various conductive elements in both electronic packages and the underlying printed circuit boards, operating frequencies can be increased.

According to an embodiment, the system can include a mounting substrate having one or more transition vias to reduce the crosstalk by separating the core vias of a differential pair. The transition vias can be configured to position a signal trace and an inverted trace further apart to improve performance.

In some embodiments, the transition via pair can be formed for a differential pair that can include a vertical interconnect for the signal line and one for the inverted signal line. The transition via pair can include the signal transition via and the inverted signal transition via adjacent to one another.

In other aspects, the inventive subject matter encompasses electronic systems configured to carry out the foregoing techniques.

### 2.0. System Overview

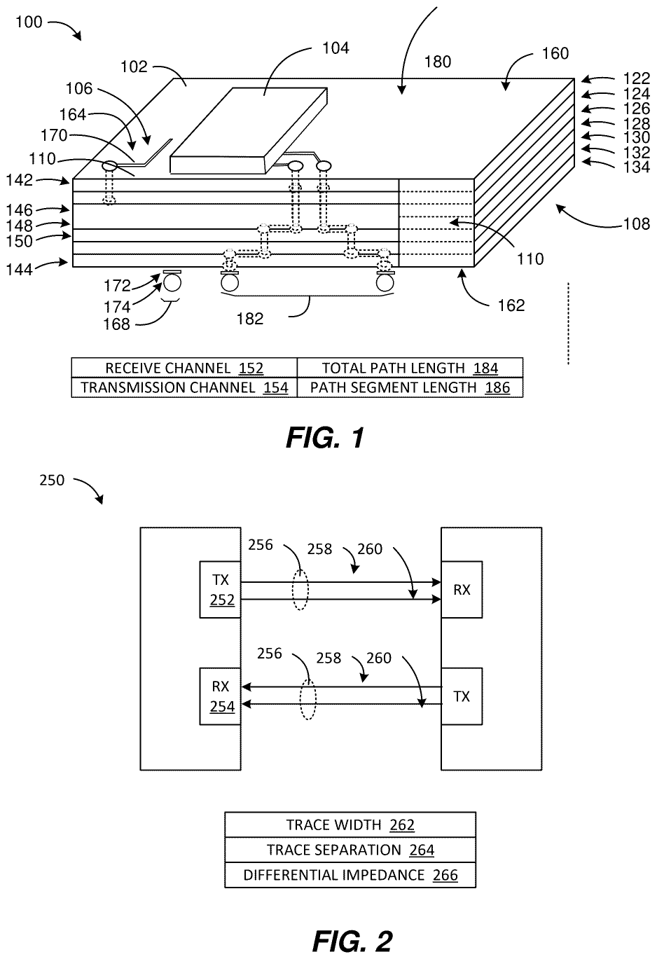

FIG. 1 illustrates an example embodiment of an electronic system 100. The electronic system 100 can have electronic components 104 attached to a mounting substrate 102. The mounting substrate 102 can couple the electronic components 104 to other ones of the electronic components 104 and to other portions of the electronic system 100.

The electronic system 100 can be a system or submodule of a system. For example, the electronic system 100 can be an electronic package, a printed circuit board, a motherboard, a daughter board, a standalone system, or other similar systems and devices.

The electronic system 100 can include one or more of the electronic components 104 attached to the mounting substrate 102. The mounting substrate 102 is a multilayer structure for coupling electronic components 104 to other electronic components 104 and to the rest of the electronic system 100. The layers of the mounting substrate 102 can have a variety of configurations. For example, the layers can be a combination of insulating materials and conductive traces transferring signals or power. The electronic components 104 can be coupled to other components with signal traces 106. The signal traces 106 are conductive paths for transferring signals and power. In another embodiment, the mounting substrate 102 can be a printed circuit board (PCB) 108, electronic package, or other similar elements.

The mounting substrate 102 can have a variety of types of different layers. In some embodiments, the mounting substrate 102 can have layers including signal trace layers, power layers, ground plane layers, insulation layers, electromagnetic shielding layers, external connection layers, and/or other similar layers.

The electronic components 104 are the elements used to provide the functionality of the electronic system 100. The electronic components 104 can be active or passive components. For example, the electronic components 104 can be active components such as integrated circuits, processors, field programmable gate arrays, transistors, ball grid array components, or other similar active components. The electronic components 104 can be passive components such as resistors, capacitors, inductors, connectors, interfaces, contact pads, or other similar passive components.

The mounting substrate 102 can include a plurality of substrate layers 111 formed from insulating and conductive materials. For example, the mounting substrate 102 can include a conductive top portion formed on an insulating dielectric portion of the substrate layer 111.

In an illustrative embodiment, the mounting substrate 102 can include a first layer 122, a second layer 124, a third layer 126, a fourth layer 128, a fifth layer 130, a sixth layer 132, and a seventh layer 134. In other embodiments, the mounting substrate 102 can be configured with a different number of layers.

The mounting substrate 102 can have a variety of configurations. The mounting substrate 102 can include a top layer 142 on a top side 160 of the mounting substrate 102, such as the first layer 122. A bottom layer 144 can be on a bottom side 162 of the mounting substrate 102, such as the seventh layer 134.

The top layer 142 can have a variety of configurations. The top layer 142 can include a top pad structure 164 having a top pad 170 electrically coupled to the via 110. For example, the top pad 170 can be a capacitor pad, a mounting pad, an interconnect pad, a surface trace, or other similar conductors.

The bottom layer 144 can have a variety of configurations. The bottom layer 144 can include a bottom pad structure 168 having a bottom pad 172 coupled to a solder ball 174. The bottom pad 172 can be a mounting pad, a solder pad, an interconnect pad, a surface pad, or other similar conductors. In some embodiments, the bottom pad structure 168 can be electrically coupled to a via, a trace, or other conductive element. In other embodiments, the solder ball 174 can be electrically coupled to an external component, such as a BGA package.

In some embodiments, the mounting substrate 102 can include one or more inner layers 146 between the top side and the bottom side. The mounting substrate 102 can include a ground layer 148, a power layer 150, signal layers, or a combination thereof.

The substrate layers 111 can be configured in a variety of ways. In some embodiments, the substrate layers 111 can have a conductive layer, such as a copper layer, formed directly on a dielectric layer, such as a fiberglass or pre-preg layer. The conductive layer can be configured to form conductive traces for conducting signals and power to the electronic components.

The substrate layers 111 can be coupled vertically with vias 110. The vias 110 are vertical conductors that can conduct signals between different layers of the mounting substrate 102. The vias 110 can be through board vias, internal vias, blind vias, stacked vias, staggered vias, buried vias, or other similar types of vertical interconnects.

In some embodiments, the via 110 can form a vertical interconnect 180 between two layers that can include two or more horizontally offset vertical segments electrically coupled together on an intermediate layer, such as two individual via segments offset from one another but both electrically coupled at an intermediate layer between the two via segments. In an illustrative example, the vertical interconnect 180 can include a top via segment offset from a middle via segment which is coupled to a bottom via segment. Each of the via segments can be one of the vias 110 such as an internal via, blind via, stacked via, staggered via, buried via, or other similar types of vertical interconnect.

The electronic components 104 can be attached to the printed circuit board 108 in a variety of ways. The electronic components 104 and the other components can be electrically coupled to the traces of the printed circuit board 108 by mounting, soldering, pressure connected, adhesive attachment, or other similar techniques.

In other embodiments, the electronic components 104, such as a ball grid array package, can be attached to the mounting substrate 102. The connection to the printed circuit board 108 can have a variety of configurations. The electronic components 104 can be attached directly to the printed circuit board 108, indirectly mounted in a socket, connected to another component, stacked, linked via a network connection, attached through a connector, or other techniques.

The configuration of the circuitry of the electronic system 100 can produce electrical effects that can impact the performance of the electronic system 100. Inductance, resistance, reactance, and capacitance are basic elemental properties of all electrical systems.

In some embodiments, the electronic system 100 can be used to provide data transmission and reception functionality. Portions of the electronic system 100 can implement functionality such as a serializer/deserializer (SerDes) circuit for converting parallel data to serial data and back. SerDes can be used to send serial data over a single line or a differential pair 182 of lines for data transmission. This can reduce pin counts and simplify interconnection requirements.

In an illustrative example, the electronic system 100 can be used to provide data communication between a first module and a second module. The modules can be integrated circuits, packages, or other electronic components. The first and second modules can be connected with the differential pair 182 of lines.

For example, portions of the electronic system 100 can implement a Pulse Amplitude Modulation 4-level (PAM4) signal encoding protocols to send and receive data in a serial fashion using four voltage levels to encode two bits of binary data. By encoding more data per unit time, the PAM4 protocol can transfer data at twice the rate of protocols such as NRZ (non-return to zero)/PAM2 protocols.

The PAM4 protocol can support different transmission frequencies. For example, the PAM4 can support signals operating at 56 Gigahertz (GHz), 112 GHz, and higher. Because PAM4 operates at higher frequencies, there is a need to improve crosstalk performance, typically below −60 dB while maintaining other electrical performance specifications such as low return loss and insertion loss.

In some embodiments, AC coupling capacitors can be used on the package to improve the data lane performance. The data lanes can include a receive lane 152 (RX lane 152) and a transmission lane 154 (TX lane 154). The electronic system 100 can send data on the transmission lane 154 and receive data on the receive lane 152. The differential pair 182 can have a total path length 184 extending the length of the path of the RX lane 152 or the TX lane 154. The differential pair 182 can include path segments such as the vertical interconnect 180, the vias 110, traces, and other similar elements. Each of the path segments can have a path segment length 186. The sum of the path segment lengths 186 can be the total path length 194.

The presence of the capacitors on package can require a large footprint area of the capacitor pads that can lead to high parasitic capacitance. In some configurations, the mounting substrate can be configured with voids below the capacitor pads. Depending on the configuration, the voids can be found to provide insufficient ground shielding. This can allow the electrical field to freely couple to adjacent lanes and impair the crosstalk performance against an even tighter crosstalk requirements. Alternatively, filling the void with ground shielding can adversely impact the return loss performance due to the capacitor pads.

In other embodiments, the package size can be increased by routing signal traces further apart. Another embodiment can increase the stackup to provide additional transition layers to allow the extra layers to add physical distance between transmission (TX) and receive (RX) interconnects.

In some embodiments, the trend of integration and miniaturization of application specific integrated circuit (ASIC) devices, the IC packages need to pack more channels of signals at higher density with faster speed. This gives rise to more challenges to meet crosstalk specs in package design. One of the main contributions of crosstalk in a FC-BGA ASIC package comes from the core vias, especially when the vias of two adjacent channels are close in physical distance. Configuring the core vias as transition vias can help reduce crosstalk.

FIG. 2 illustrates an example embodiment of the electronic system 200. The electronic system 200 can implement a serial communication subsystem.

In some embodiments, a SerDes subsystem 250 can transfer data over a RX lane 254 and a TX lane 252. The RX lane 254 can include a differential pair 256, such as a differential trace pair on the mounting substrate 202. The differential pair 256 can include traces on one or more layers of the mounting substrate 202 and the vertical interconnect between layers, and the individual via segments of the vertical interconnect 230. The first trace can be a positive trace and carries the original signal. The second trace can be a negative trace and carry the inverse of the original signal. Carrying the signal over the combination of the positive trace and the negative trace can reduce electromagnetic interference.

The SerDes subsystem 250 can be configured with a receive lane (RX lane) 254 and a transmission lane (TX lane) 252. Each lane can carry data and includes the differential pair 256, such as a PCB differential trace.

Each of the differential pairs 256 can have a data line 258 and an inverted line 260. The data line 258 can be a data signal line, a data signal trace, a main line, a signal path, or similar terms. The inverted line 260 can be an inverted signal line, an inverted signal trace, an inverted signal path, a complement line, a reference line, or similar terms.

In some embodiments, the data line 258 can carry a data signal with serial encoded data. The inverted line 260 carries an equal and opposite polarity version of the data signal. Each of the individual lines can have a characteristic impedance based on a trace width 262 and a trace spacing 264 between the other paired trace. The differential pairs 256 together can have a differential impedance 266. The length of the two lines in the differential pair 256 can have substantially the same length to facilitate the signals arriving at their destination at the same time. This can include the length through all of the portions of the differential pair 256 connection, from source to destination including traces, pads, vias, via segments, and external connection between components. In some embodiments, the lengths of the two lines in the differential pair 256 can be substantially the same length within one half of a wavelength of the frequency of the signals carried on the two lines.

The differential pairs 256 can be routed together horizontally and vertically through the mounting substrate 202. The differential pairs 256 can traverse different layers using the vertical interconnect 230 having one or more of the via segments 228. Each of the via segments 228 can span one or more layers 208. In some embodiments, the via segments 228 can be directly connected together in a vertical configuration, offset from one another and connected together with a horizontal trace, or a combination thereof. A single one of the via segments 228 standing alone can be a via 220.

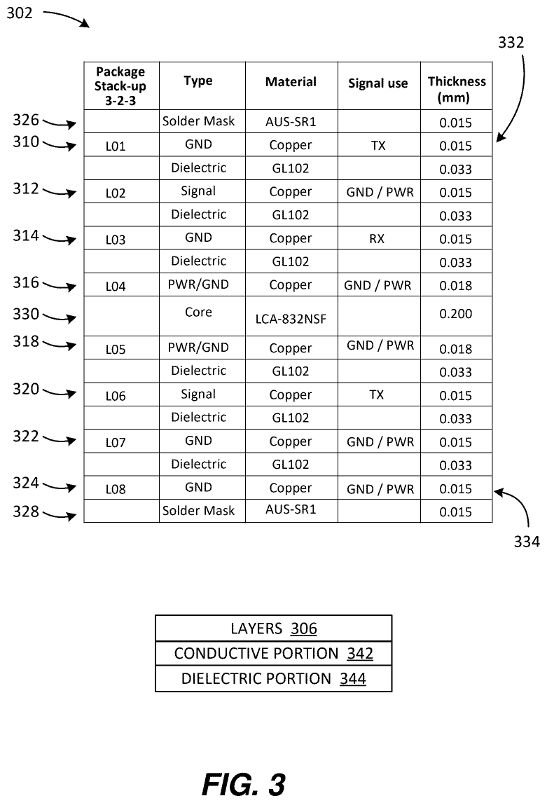

FIG. 3 illustrates an example embodiment of the mounting substrate 302. The mounting substrate 302 can be an electromechnaical structure for routing and transferring signals and power to components coupled to the mounting substrate 302.

The mounting substrate 302 can have a variety of configurations. For example, the mounting substrate 302 can be a package substrate, a printed circuit board, flexible circuit board, a chip package, a daughter board, or other similar structure.

The mounting substrate 302 can have multiple layers 306 in direct contact with each adjacent layer. The layers 306 can include signal routing layers, power plane layers, ground play layers, power routing layers, thermal management, electromagnetic shielding, or other similar functions.

In some embodiments, the layers 306 can include conductive portions 342 and dielectric portions 344 bonded together. The conductive portions 342 can be formed from copper, gold, aluminum, or other conductive substances. The conductive portions 342 can include signal traces, power traces, power planes, ground traces, ground planes, or a combination thereof.

The dielectric portions 344 can be formed using a dielectric material 354 such as epoxy, resin, plastic, polymers, fiberglass, pre-impregnated (“pre-preg”) materials, or other similar materials. The dielectric portions 344 can form the structural base of each of the layers with the conductive portions 342 forming traces, vias, and planes on and through the layers.

The dielectric portions 344 can be formed using different dielectric materials such as Taiyo™ AUS-SR1, Ajinomoto Build-Up Film® GL102, Mitsubishi® 832NSF-LCA, or similar materials. The dielectric materials have properties such as a low dielectric constant (Dk) and low dielectric loss (Df). In some embodiments, a glass substrate can have a dielectric constant of 5.4 and a dielectric loss of 0.005 at 10 gigahertz (GHz). A dielectric material such as GL102 can have a dielectric constant of 3.3 and a dielectric loss of 0.0044 at 5.8 GHz.

In some embodiments, the mounting substrate 302 can be configured with different numbers of layers. For example, the mounting substrate 302 can have eight layers such as a first layer 310, a second layer 312, a third layer 314, a fourth layer 316, a fifth layer 318, a sixth layer 320, a seventh layer 322, and an eighth layer 324. The mounting substrate 302 can include a top layer 332 and a bottom layer 334.

In some embodiments, the mounting substrate 302 can include one or more core layers 330. The core layers 330 can also be designated base layers. The core layers 330 are located in the middle of the mounting substrate 302 and can be formed with different dielectric materials than the other layers. During manufacture, the other layers can be formed on the top and bottom of the core layers 330. The mounting substrate 302 can be configured as a single sided or double-sided substrate. For example, the mounting substrate 302 can be single-sided PCB, a double-sided PCB, an electronic package substrate, or other similar configurations.

In some embodiments, the layers 306 can be configured as described below. The first layer 310 can be configured as a ground layer having a conductive layer with a thickness of 0.015 millimeters (mm) and the dielectric with a thickness of 0.033 mm. The first layer 310 can be used for transmission functions.

The second layer 312 can be configured as a signal layer formed having a conductive layer with a thickness of 0.015 mm and a dielectric layer with a thickness of 0.033 mm. The second layer 312 can be used for power and ground functions.

The third layer 314 can be configured as a ground layer formed having a conductive layer with a thickness of 0.015 and a dielectric layer with a thickness of 0.033 mm. The third layer 314 can be used for receiving functions.

The fourth layer 316 can be configured as a power and ground layer and formed on a core layer 330. The conductive layer can have a thickness of 0.018 mm and the core layer 330 can have a dielectric layer with a thickness of 0.200 mm. The core layer 330 can be formed with a dielectric material such as 832NSF-LCA. The fourth layer 316 can be used for power and ground functions.

The fifth layer 318 can be a power and ground layer and formed on the core layer 330. The fifth layer 318 can be formed on a bottom side of the core layer 330. The fifth layer 318 can have a conductive layer formed directly on the core layer 330. The fifth layer 318 can have a dielectric layer formed directly on the conductive layer. The fifth layer 318 can have a conductive layer with a thickness of 0.015 mm and a dielectric layer with a thickness of 0.033 mm.

The sixth layer 320 can be configured as a signal layer formed having a conductive layer with a thickness of 0.015 mm and a dielectric layer with a thickness of 0.033 mm. The sixth layer 320 can be used for transmission functions.

The seventh layer 322 can be configured as a ground layer formed having a conductive layer with a thickness of 0.015 mm and a dielectric layer with a thickness of 0.033 mm. The sixth layer 320 can be used for power and ground functions.

The eighth layer 324 can be configured as a ground layer formed having a conductive layer with a thickness of 0.015 mm and a dielectric layer with a thickness of 0.033 mm. The eighth layer 324 can be used for power and ground functions.

The mounting substrate can include protective solder mask layers on the outer layers of the mounting substrate 302. The solder mask layers can include a top solder mask layer 326 over the first layer 310 and a bottom solder mask layer 328 below and in direct contact with the bottom layer, such as the eighth layer 324. The solder mask layers can be protective layers of material configured to protect the underlying layer from oxidation, corrosion, contamination, dust, dirt, liquids, short circuits, or other contaminants during operation.

In some embodiments, the mounting substrate 302 can be a double-sided printed circuit board having the core layer 330. The mounting substrate 302 can be formed by applying additional layers on the top and bottom side of the core layer 330. The mounting substrate 302 can be formed by forming the fourth layer 316 and the fifth layer 318 directly on the core layer 330. The third layer 314 can then be formed on the fourth layer 316 and the sixth layer 320 can be formed on the fifth layer 318. The second layer 312 can be formed on the third layer 314 and the seventh layer 322 can be formed on the sixth layer 320. The first layer 310 can be formed on the second layer 312 and the eighth layer 324 can be formed on the seventh layer 322. The top solder mask layer 328 can be formed on the first layer 310 and the bottom solder mask layer 328 can be formed on the eighth layer 324.

In some embodiments, the layers of the mounting substrate 302 can be formed in different ways depending on the manufacturing technology used. Each of the layers 306 can include the conductive layer and the dielectric layer.

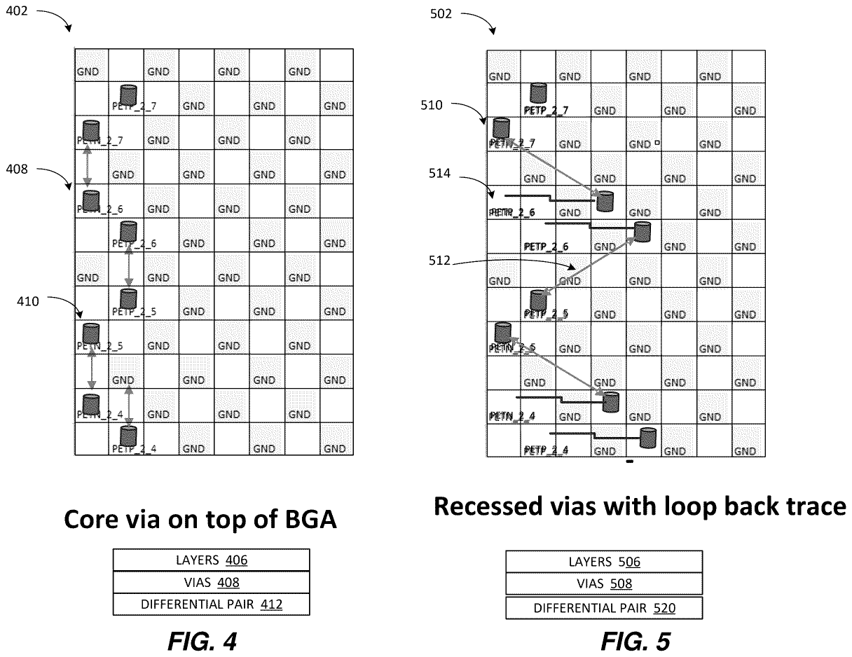

FIG. 4 illustrates an example embodiment of a mounting substrate 402 of a ball grid array package. The mounting substrate 402 can have contact pads 422 arranged in a checkerboard pattern on a bottom side of the mounting substrate 402, such as on a ball grid array package. The mounting substrate 402 can include multiple layers 406 with a ball grid array of contact pads 422 coupled to signal core vias 410 extending between the layers 406.

The mounting substrate 402 can include the signal core vias 410 extending through multiple layers 406 of the mounting substrate 402. A semiconductor package can be attached to one side of the mounting substrate 402.

In some embodiments, the signal core vias 410 can be positioned on a top side contact pads, such as BGA pads 408. The BGA pads 408 can be closely packed and tightly coupled. However, this can lead to high crosstalk between adjacent signal lines, such as the lines of the differential pairs. In yet other embodiments, the signal core vias 410 can be formed directly on top of the package BGA pads 408 to save space. However, as package routing densities increase the space between the signal core vias 410 are reduced while the acceptable levels of crosstalk is getting tighter due to faster protocols, such as PCIE6 and PCIe7.

The signal core vias 410 can be part of the path of differential pairs 412. The differential pairs 412 are pairs of conductors carrying complementary signals. One line can carry the original signal while the other line of the differential pair can carry an inverted signal.

The differential pairs 412 can carry the signals from one side of the mounting substrate 402 to the other side of the mounting substrate 402. In an illustrative embodiment, one side of the mounting substrate 402 can be used to attach to the ball grid array package while the other side can be used to attach to a component, such as a semiconductor die.

FIG. 5 illustrates another example embodiment of the mounting substrate 502. The mounting substrate 502 can include multiple layers 506 with contact pads 560 coupled to vias 508 extending between the layers 506. The mounting substrate 502 can exhibit electrical crosstalk between the vias 508 of the differential pair 520.

In some embodiments, the vias 508, such as signal core vias, can be selectively recessed to create a staggered via-to-via pattern which allows for bigger distances between the vias. This configuration can reduce the potential crosstalk and other electromagnetic signal interference. The loop-back trace 514 can then connect the recessed vias to the BGA ball on a different layer 506. The loop-back trace offers improved compensated inductive performance as shown below.

In some embodiments, the loop-back trace 514 configuration can allow a separation distance 512 of 1375 um to 2813 um. However, other separation distances 512 can be utilized.

The recessed vias and the transition vias can be configured in a variety of ways. In other embodiments, the recessed vias can be formed using an alternating pattern such as a “10101” pattern. In other configurations, the recessed vias can be configured in a “1001001” pattern. In addition, the loop back trace can be formed on different layers. The vias can also be recessed toward different directions, such as by making the traces longer instead of shorter. In some larger BGA package embodiments, the BGA package can be greater than 10 mm×10 mm.

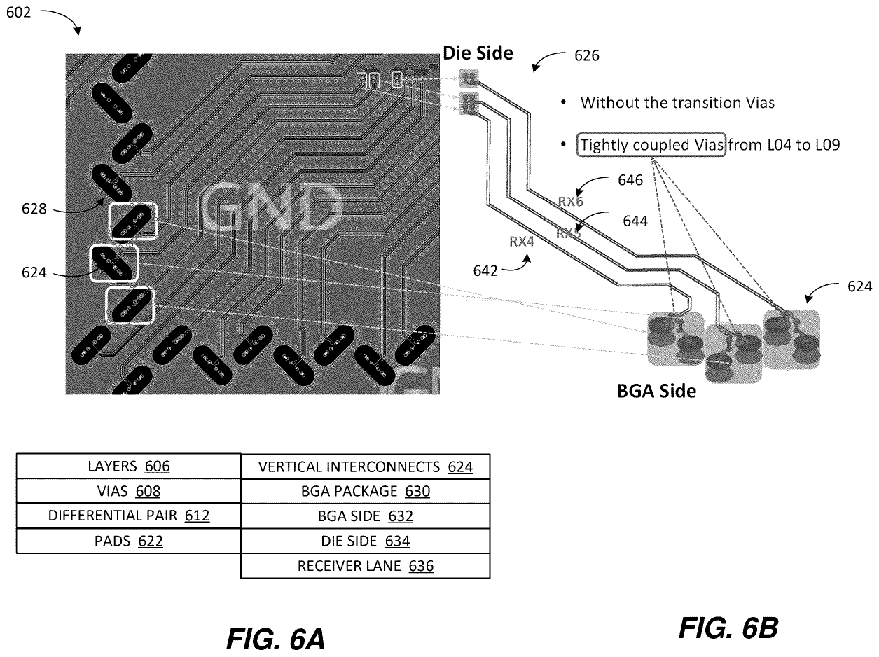

FIGS. 6A and 6B illustrate example embodiments of differential pairs 612 on a mounting substrate 602. The differential pairs can carry receiver signals 604 (RX signals 604) between a die side 634 of the mounting substrate 602 and a ball grid array side of the mounting substrate in a tightly coupled configuration.

FIG. 6A illustrates an example embodiment of the mounting substrate 602 in a tightly coupled configuration. The mounting substrate 602 can have contact pads 622 exposed on a die side 634 of the mounting substrate 602. The contact pads 622 can be electrically coupled to receiver lanes 636 and vertical interconnects 624.

In some embodiments, the vertical interconnects 624, such as vias 608, can be arranged in voids 628 and close to one another. This results in the vias 608 that are tightly coupled due to their proximity.

FIG. 6B illustrates an example embodiment of the differential pairs 612 on the mounting substrate 602 of a ball grid array package 630. The differential pairs 612 can extend from contact pads 622 on the die side 634 of the mounting substrate 602 mounting substrate 602 can have contact pads 622 exposed on a ball grid array side 632 of a mounting substrate 602. The contact pads 622 can be electrically coupled to the receiver lanes 626 and vertical interconnects 624.

In an illustrative embodiment, the mounting substrate 602 can have several receiver lanes 636 extending from contact pads 622 on a die side 634 coupled to differential pairs 612 and extending to the vias 608, such as tightly coupled vias, on the BGA side 632 of the mounting substrate 602.

For example, the mounting substrate 602 can have a fourth receiver lane 642, a fifth receiver lane 644, and a sixth receiver lane 646. The vias 608 of the receiver lanes 626 are adjacent to one another and are tightly coupled due to their proximity.

In some embodiments, a novel via array arrangement scheme to stagger the adjacent vias so the distances between vias are increased within the same package configuration. The additional loop-back trace in the staggered via structure also offers another benefit of compensated inductive trace that helps reduce unwanted channel return loss.

In some other embodiments, the vias 608, such as signal core vias, can be located on top of the BGA pads and are closely packed and tightly coupled. This configuration can lead to high crosstalk between the adjacent channels.

Additionally, the signal core vias can be selectively recessed to create a staggered via-to-via pattern which allows bigger distance and therefore much lower crosstalk. The loop-back trace can connect the recessed vias to the BGA ball in a different layer. This loopback trace offers compensated inductive benefits as will be shown in the following result slides.

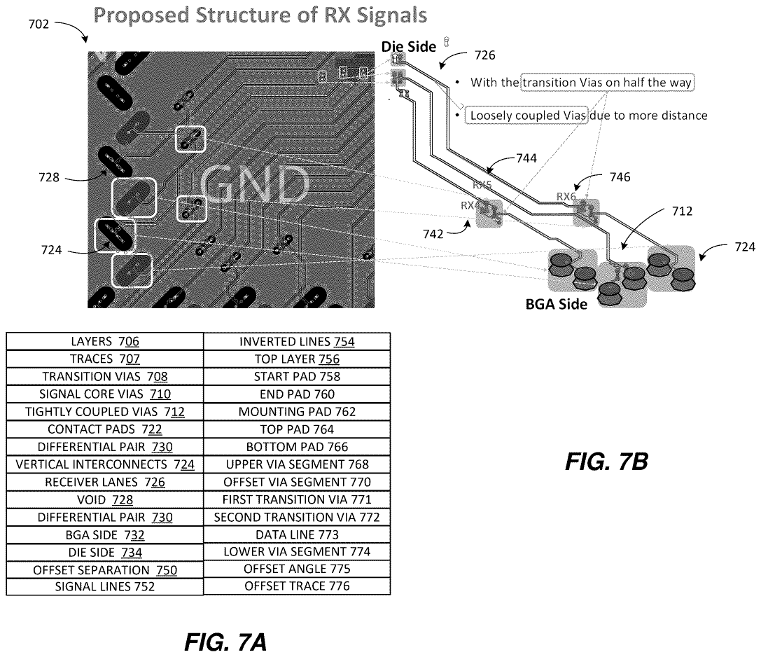

FIGS. 7A and 7B illustrate example embodiments of differential pairs 730 on a mounting substrate 702. The differential pairs can carry receiver signals between a die side 720 of the mounting substrate 702 and a ball grid array side 732 of the mounting substrate in a tightly coupled configuration.

FIG. 7A illustrates an example embodiment of the mounting substrate 702 in a loosely coupled configuration. The mounting substrate 702 can have contact pads 722 exposed on a die side 634 of the mounting substrate 702. The contact pads 722 can be electrically coupled to receiver lanes 726 and vertical interconnects 724.

In some embodiments, the vertical interconnects 724, such as signal core vias 710, can be arranged in offset locations to increase distance between the signal core vias 708 and help reduce the degree of coupling between the signal core vias 708. This can in transition vias 708 that are loosely coupled due to the additional distance between them due to the offset provided by the transition vias 708.

FIG. 7B illustrates an example embodiment of the differential pairs 730 on the mounting substrate 702 of a ball grid array package 630. The differential pairs 730 can extend from contact pads 722 on the die side 634 of the mounting substrate 702 mounting substrate 702 can have contact pads 722 exposed on a ball grid array side 732 of a mounting substrate 702. The contact pads 722 can be electrically coupled to the receiver lanes 726 and vertical interconnects 724.

In an illustrative embodiment, the mounting substrate 702 can have several of the receiver lanes 726 extending from contact pads 722 on a die side 734 coupled to differential pairs 730 and extending to tightly coupled vias 712 on the BGA side 732 of the mounting substrate 702.

For example, the mounting substrate 702 can have a fourth receiver lane 742, a fifth receiver lane 744, and a sixth receiver lane 746. The vertical interconnect 724 of the receiver lanes 726 are adjacent to one another and are tightly coupled due to their proximity.

The differential pairs 730 can include transition vias 708 positioned between the contact pads 722, such as BGA side pads, and the contact pads 722, such as die side pads. The transition vias 708 can be offset from one another to make the transition vias 708 loosely coupled. The transition vias 708 can be offset by a transition via offset separation 750.

In an illustrative embodiment, the fourth receiver lane 742 can be configured with the transition vias 708 approximately half-way between the start and end points of the lane. The sixth receiver lane 746 can be configured with the transition vias 708 approximately half-way between the start and end points of the sixth receiver lane 746. The fifth receiver lane 744 can be configured with the transition vias 708 near the BGA side pads. The transition vias 708 are loosely coupled because they are separated by the transition via offset separation 750. The transition vias 708 of the fourth receiver lane 742 and the fifth receiver lane 744 are separated by the transition via offset separation 750.

The vertical interconnects 724 can be surrounded by a void 728. The void 728 is a non-conductive volume. The formation of traces 707 and vias 708 can define a void 728. In some embodiments, the void 728 can be formed on one or more layers and is a volume within the layers 706 that is devoid of conductive materials.

The transition vias 708 can be formed and coupled to the traces 707 of the layer 706. The traces 707 can include the signal lines 752 and the inverted lines 754, as well as the structures of the transition vias 708. Because of the related nature of the traces and the vias, the ordering and interleaving of the three steps can be repeated as necessary to form the conductive structures.

In some other embodiments, the vertical interconnects 724 can be formed in a near adjacent area of the mounting substrate 702. The top layer 756 of the mounting substrate 702 can be configured in a checkerboard layout and the vertical interconnects 724 can be positioned to be offset from both a start pad 758 and an end pad 760, such as mounting pads 762.

The vertical interconnect 724 can be a transition via 708. The transition via 708 can be a structure having a multi-part via having two or more via segments 764 that are horizontally offset from one another.

The transition vias 708 can include several elements. The transition via 708 can have a top pad 764, a bottom pad 766, an upper via segment 768, an offset via segment 770, an offset trace 776, and a lower via segment 774.

In some embodiments, the transition via 708 can be positioned between the start point and the end point and configured to maximize the distance between the two points and the transition via 708. In one configuration, the transition via 708 is positioned in the middle of the differential pair 730. In another configuration, the transition via 708 is positioned between 40% and 60% of the length of the differential pair 730. Other configurations can be used with the transition via 708 positioned along the differential pair 730. The transition vias 708 can include a first transition via 771 and a second transition via 772.

The transition via 708 can be configured to carry both lines of the differential pair 730, the data line 773 and the inverted line 754. In some embodiments, the upper via segment 768 of the data line 773 can be positioned directly away from the upper via segment 768 of the inverted line 754. In still other embodiments, the upper via segment 768 of the data line 773 can be positioned away from the upper via segment 768 of the inverted line 754 by an offset angle 775 in the range of −60 degrees and 60 degrees. can be offset from the upper via segment 768 of the inverted line 754.

In another embodiment, the upper via segment 768 of one of the lines can be offset horizontally by the offset trace 776. The length of the offset trace 776 can be configured to reduce the impedance of the transition via 708.

In some embodiments, the transition vias 708 can be formed in a variety of ways. For example, the hole of the body of the transition vias 708 can be formed by etching, drilling, sawing, laser drilling, chemical etching, photoetching, or other similar techniques. Afterward, the hole formed for the transition vias 708 can be plated or filled with conductive material to form the conductor of the transition vias 708.

The traces 707 can be formed in a variety of ways. In some embodiments, the traces 707 formed on the layers 706 of the mounting substrate 702 can be formed by plating, photoetching, photolithography, chemical vapor deposition, grinding, cutting, and other similar techniques.

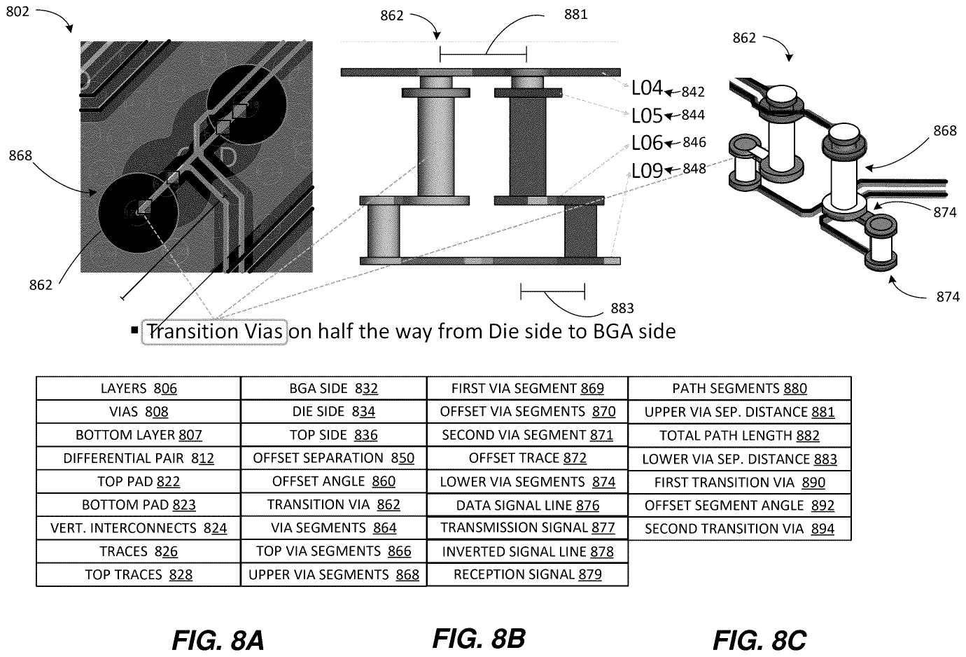

FIGS. 8A, 8B, and 8C illustrate example embodiments of a transition via 862. The transition via 862 are vertical interconnects 824 for electrically connecting different layers 806 of the mounting substrate 802. Each of the layers 806 can support different functionality and different electrical connectivity between the layers 806 of the mounting substrate 802.

FIG. 8A illustrates an example embodiment of a top view of the transition via 862 on the mounting substrate 802. The mounting substrate 802 can be an electromechnaical structure for routing and transferring signals and power to components coupled to the mounting substrate 802.

In some embodiments, the transition vias 862 can conduct electrical signals from one side of the mounting substrate to the other side. For example, the transition vias 862 can transfer signals from a top layer 842, such as a die side 834, to a ball grid array side 832 (BGA side 832).

The mounting substrate 802 can include traces 826, such as traces 826 for a differential pair line. The top traces 828 can be on a top side 836 of the mounting substrate 802. Each of the top traces 828 can be electrically coupled to one of the vertical interconnects, such as one of the transition vias 862.

In some embodiments, the transition vias 862 can be configured at different locations as the differential pair 812. In an illustrative embodiment, the transition vias 862 can be positioned at approximately halfway between the start of the differential pair 812 on one side of the mounting substrate 802 and the end of the differential pair 812 on the opposite side of the mounting substrate 802.

FIG. 8B illustrates an example embodiment of a side view of the transition via 862. The transition via 862 can include multiple segments extending through the layers 806 of the mounting substrate 302.

The transition vias 862 are the vertical interconnects 824 that connect the via segments 864 that are horizontally offset from one another. In some embodiments, the transition vias 862 can include a plurality of the via segments 864 extending through one or more of the mounting substrate 802. The transition vias 862 can include a top pad 822, a bottom pad 823, a top via segment 866, an upper via segment 868, an offset via segment 870, an offset trace 872, and a lower via segment 874.

With reference to the mounting substrate 802, a vertical direction can be the direction from the top layer 842 to the bottom layer 807 of the mounting substrate 802. A horizontal direction can be in a direction perpendicular to the vertical direction. The horizontal direction can be a direction parallel to one of the layers 806 of the mounting substrate 802. The directions of horizontal and vertical can be described as orthogonal to one another.

In some embodiments, the upper via segment 868 and the offset via segment 870 can be horizontally offset from one another and electrically coupled to an offset trace 872.

The transition vias 862 can have a variety of via segment configurations. The transition vias 862 can be configured as part of the differential pairs 812 where two conductive paths carry the data signal line 876 and the inverted signal line 878 to reduce electrical interference and signal noise. The data signal line 876 and the inverted signal line 878 have the substantially the same value of a line length.

In embodiments where the differential pair 812 carrying a signal, such as a transmission signal 877 (TX signal 877) or a reception signal 879 (RX signal 878), need to be routed to a different one of the layers 806 of the mounting substrate 802, the differential pair 812 can be configured with a pair of the vertical interconnects 824, such as the transition vias 862.

The upper via segments 868 can be separated by an upper via separation distance 881. The lower via segments 874 can be separated by a lower via separation distance 883. One of the upper via segments 868 can be offset from the lower via segment 874 along the same conductive path by an offset separation 850. One of the upper via segments 868 can be offset from one of the lower via segments 874 of the other conductive path of the same one of the differential pair 812 by the offset separation 850.

The via segments 864 of the transition vias 862 can have a variety of layer configurations. In an illustrative embodiment, the top via segment 866 can be electrically coupled to the traces 826 of the differential pair 812 on the fourth layer 842 and the fifth layer 844. The upper via segment 868 can be electrically coupled between the fifth layer 844 and the sixth layer 846. The upper via segment 868 can be electrically coupled to the offset via segment 870 through the offset trace 872. The offset via segment 870 can be electrically coupled to the bottom pad 823.

FIG. 8C illustrates an example embodiment of the transition vias 862. The transition via 862 can include multiple segments extending through the layers 806 of the mounting substrate 302.

In some embodiments, each of the differential pair 812 can include two of the lines configured as a data signal line 876 and an inverted signal line 878. Each of the lines can be electrically coupled to one of the transition vias 862. The differential pair 812 can have a total path length 882. The differential pair 812 can include two or more of the path segments 880 such as trace segments, vertical interconnects, pads, and other similar elements.

The transition vias 862 can have a variety of structural configurations. In some embodiments, the offset via segment 870 can be in different positions relative to the upper via segment 868. The offset via segment 870 can be positioned at an offset angle 860 from the upper via segment 868. The offset angle 860 can be measured in a variety of ways. In some cases, the offset angle 860 can be measured between the major axis of the offset trace 872 and a line connecting the two upper via segments. Alternatively, the offset angle 860 can be measured between the offset trace 872 and a line connecting the two lower via segments.

The offset angle 860 can be measured in a variety of ways. For example, the offset angle 860 can be measured relative to the trace 826 connected to the top of the transition via 862, relative to the trace connected to the bottom of the transition via 862, relative to the long axis of the semiconductor die, relative to a defined direction, or using other similar techniques.

In some embodiments, the differential pairs 812 can be configured with each of the lines having the transition vias 862 at different values of offset segment angles 892. By configuring the offset segment angles 892, such as a first offset angle and a second offset angle, the distance between the two offset via segments 870 can be controlled to modify the electrical characteristics such as loop impedance, electromagnetic interference, and other similar characteristics. In an illustrative example, the first offset angle can be 180 degrees, while the second offset segment angle can be 45 degrees. The difference in the offset segment angles 892 can be due to geometric and surface area limitations in the overall package design.

The data signal line 876 can include the transition via 862 between the start and end points. The transition via 862 extends through one or more layers 806 and can include two or more of the via segments 864 that are horizontally offset from one another. The transition vias 862 can include at least a first via segment 869 and a second via segment 871 electrically connected with a horizontally running transition via trace 826.

In some embodiments, two of the transition vias 862 can be configured with the lower via segment 874 of the first transition via 890 positioned away from the lower via segment 874 of a second transition via 894 to have the maximum separation between the two of the lower via segments 874.

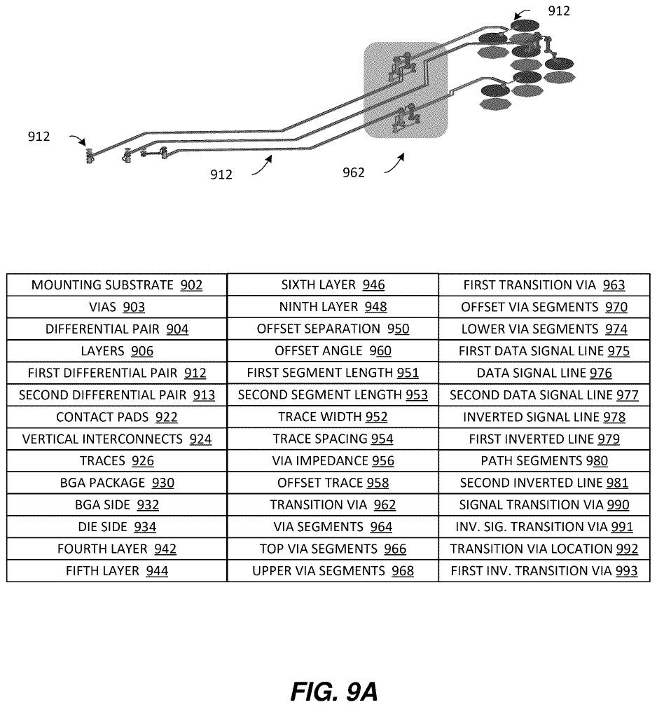

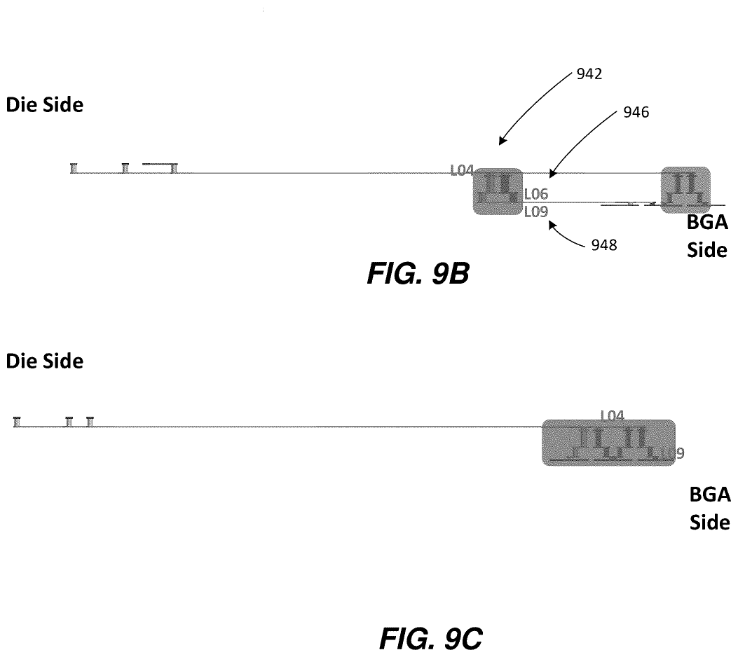

FIGS. 9A, 9B, and 9C illustrate example embodiments of a differential pair 904. The differential pair 904 can include vertical interconnects 924 for electrically connecting different layers 906 of the mounting substrate 902. Each of the layers 906 can support different functionality and different electrical connectivity between the layers 906 of the mounting substrate 902.

FIG. 9A illustrates an example embodiment of the differential pair 904 with transition vias 962. The transition vias 962 can include multiple segments extending through the layers 906 of the mounting substrate 302.

The differential pair 904 is a pair of conductive paths for transferring data signals from a source point to the destination point.

The differential pair 904 can be configured to have a data signal line 976 and an inverted signal line 978. The data signal line 976 can be a data line, a data trace, a data signal trace, a main line, a signal path, or similar terms. The inverted signal line 978 can be an inverse trace, reference signal line, an inverted line, an inverted signal trace, an inverted signal path, a complement line, a reference line, or similar terms. The data signal line 976 can carry a data signal with serial encoded data. The inverted signal line 978 carries an equal and opposite polarity version of the data signal.

Each of the individual lines can have a characteristic impedance based at least partially on a trace width 952 and a trace spacing 954 between the other paired trace. Each of the transition vias 962 can also have a via impedance 956 based on the structural layout of the transition vias 962.

Each of the differential pair 904 together can have a differential impedance. The length of the two lines in the differential pair 904 can have substantially the same length to facilitate the signals arriving at their destination at the same time. This can include the length through all of the portions of the differential pair 904 connection, from source to destination including traces, pads, vias, via segments, and electronic connections between components. In some embodiments, the lengths of the two lines in the differential pair 904 can be substantially the same length within one half of a wavelength of the frequency of the signals carried on the two lines.

The differential pair 904 can include the transition vias 962 for transferring the signals to different layers 906 of the mounting substrate 902. The transition via location 992 is the location of the transition vias 962 on the differential pair 912. Because the differential pair 904 have two lines, the transition vias 962 can include a signal transition via 908 and an inverted transition via 991.

In some embodiments, the differential pair 904 can have a first segment length 951 and a second segment length 953. The first segment length 951 is the distance between the starting point of the differential pair 904 and the location of the transition via 962. The second segment length 953 is the distance between the transition via 962 and the ending point of the differential pair 904. In some embodiments, the lengths can be measured in terms of the absolute physical distance between the two points on the mounting substrate 902, the electrical distance of the path between the two points, the physical routing distance between the two points, or other similar techniques. The physical routing distance can be defined as the distance along the conductors of the conductive path formed by each of the lines of one of the differential pair 904.

In some embodiments, a first differential pair 912 and a second differential pair 913 can have a via pair separation 926. The via pair separation 926 is the distance between the transition via 962 of the first differential pair 912 and another transition via 962 of the second differential pair 913.

Increasing the via pair separation 926 between the first differential pair 912 and the second differential pair 913 can reduce the impedance coupling between the two of the transition vias 962. In this case, the transition vias 962 can be loosely coupled to one another. The larger the via pair separation 926, the lower the impedance coupling.

The location of the transition vias 962 can be defined in a variety of ways. In one example, the transition via location 992 can be represented by the point between both of the upper via segments 968, the position of one of the upper via segments 968, the position of one of a lower via segment 974, the point between two of the lower via segments 974, or a position between a set of four of the upper and lower via segments 974.

FIG. 9B illustrates an example embodiment of a side view of differential pairs 904 with the transition vias 902. The transition via 962 can include multiple segments extending through the layers 906 of the mounting substrate 302.

In an illustrative embodiment, the side view shows a first differential pair 912 and a second differential pair 913 on the mounting substrate 902. In some side views, the one of the differential pair 904 may obscure the other.

The differential pair 904 can include two lines such as a data signal line 976 and the inverted signal line 979. The first differential pair 912 can include the first data signal line 975 and the first inverted line 979. The second differential pair 913 can include a second data signal line 977 and a second inverted line 981.

The first data signal line 975 can include a first transition via 963 at a first via distance from the first start point and a second via distance from the first end point.

The first inverted line 979 can include a first inverted transition via 993 at a first inverted via distance from the first start point and second via distance from the first end point. The first start point can be a contact or pad where a component can be attached. The first start point can be a contact or pad where a component can be attached.

FIG. 9C illustrates an example embodiment of a side view of a differential pair 904 with vias 903. The via 903 can include multiple segments extending through the layers 906 of the mounting substrate 902.

The differential pair 904 can be routed together horizontally and vertically through the mounting substrate 902. The differential pair 904 can traverse different layers using the vertical interconnects 924 having one or more of the via segments 964. Each of the via segments 964 can span one or more layers 906. In some embodiments, the via segments 964 can be directly connected together in a vertical configuration, offset from one another and connected together with an offset trace 958. The offset trace 958, such as a horizontal trace or pad, can be a conductive structure to allow the positioning of the via segments 964.

In an illustrative embodiment, each of the vias 903 can be positioned near the end point of the differential pair 904. This can result in the vias 903 being tightly coupled due to their proximity.

In another embodiment, the vias 903 can be positioned near the end point of the differential pair 904, such as adjacent to the contact pads 922. In some configurations, the contact pads 922 can be positioned close to one another, such as when the contact pads 922 are configured to electrically couple to the contacts of the ball grid array component. For example, the ball grid array component can be configured with a via 908 directly under the contact pad 922 or in an adjacent location.

In one embodiment, the vias 903 can be near the end point of the differential pair 904, such as adjacent to the contact pads 922. In some configurations, the contact pads 922 can be positioned close to one another, such as when the contact pads 922 are configured to electrically couple to the contacts of the ball grid array component.

In yet another embodiment, the via 903 can extend from a fourth layer 942 of the mounting substrate 902 through a fifth layer 944, a sixth layer 946, and a ninth layer 948 of the mounting substrate 902. This can be a configuration on the die side of the mounting substrate or the BGA side 632.

### 3.0. Performance Analysis

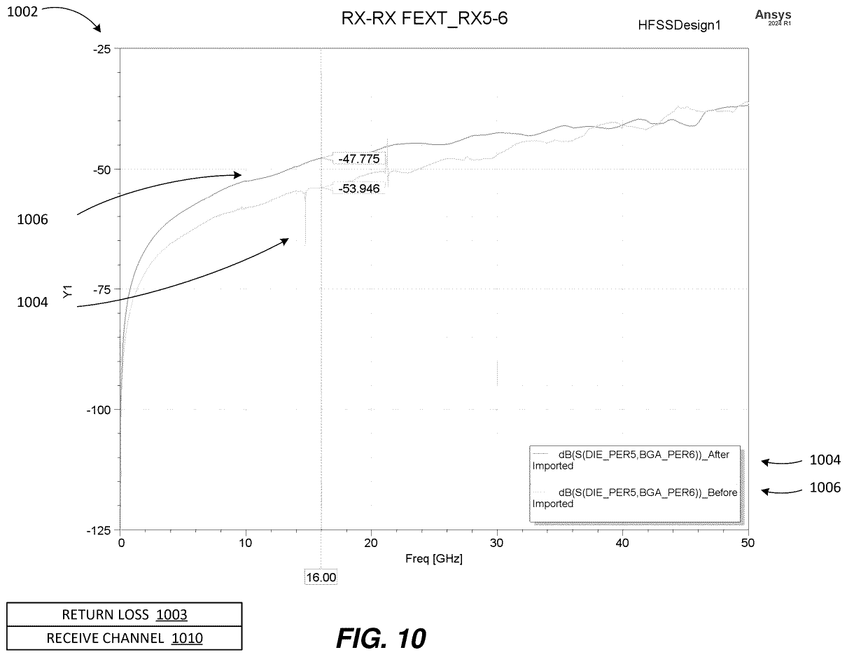

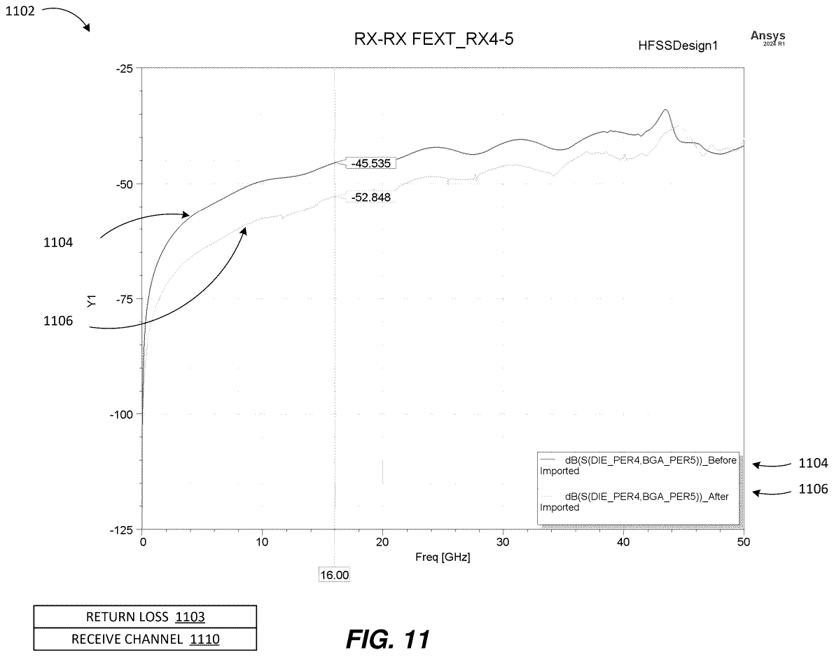

FIG. 10 illustrates an example of a receiver-receiver return loss graph 1002 (RX-RX return loss graph 1002) for an embodiment of the electronic system 100. The return loss graph 1002 shows return loss 1003 for an electrical signal loss in decibels over a range of frequencies for a receive channel 1010.

The RX-RX return loss graph 1002 can show the amount of signal power reflected back to the source along an electrical element. A higher value of the return loss 1003 shows lower reflection and better signal and power transmission. The return loss 1003 can be expressed as the logarithmic ratio of the power reflected back along the electrical element.

In some embodiments, the return loss graph 1002 can show the return loss 1003 for different configurations. The return loss graph 1002 can show an optimized return loss at approximately 16 GHz with the return loss at approximately 6.171 dB.

The return loss graph 1002 shows separate curves for different configurations. For example, the first curve 1004 can represent the return loss of a die PERO. The second curve 1006 can represent the return loss of a die PER1. The third curve 1008 can represent the return loss of a die B_PER0. And the fourth curves 1010 can represent the return loss of a die B_PER1.

In some embodiments, the first curve 1004, such as a before curve, can have a value of −47.775 at 16 GHz. The second curve 1006, such as an after curve, can have a value of 53.946 at 16 GHz. In addition, the second curve 1006 can show a significant drop of about 15 dB from approximately −55 to −70 dB at 15 Ghz. In addition, a rise of approximately 10 dB was shown from −55 to −45 at approximately 21 Ghz.

FIG. 11 illustrates an example of a receiver-receiver return loss graph 1102 (RX-RX return loss graph 1102) for an embodiment of the electronic system 100. The return loss graph 1102 shows return loss 1103 for an electrical signal loss in decibels over a range of frequencies for a receive channel.

The RX-RX return loss graph 1102 can show the amount of signal power reflected back to the source along an electrical element. A higher value of the return loss 1103 shows lower reflection and better signal and power transmission. The return loss 1103 can be expressed as the logarithmic ratio of the power reflected back along the electrical element.

In some embodiments, the return loss graph 1102 can show the return loss 1103 for different configurations. The return loss graph 1102 can show an optimized return loss at approximately 16 GHz with the return loss at approximately 7.3 dB.

The return loss graph 1102 shows separate curves for different configurations. For example, the first curve 1104 can represent the return loss of a die PER4. The second curve 1106 can represent the return loss of a die PER4.

In some embodiments, the first curve 1104, such as a before curve, can have a value of −45.535 at 16 GHz. The second curve 1106, such as an after curve, can have a value of 52.848 at 16 GHz. Thus, the improvement is approximately −7.3 dB.

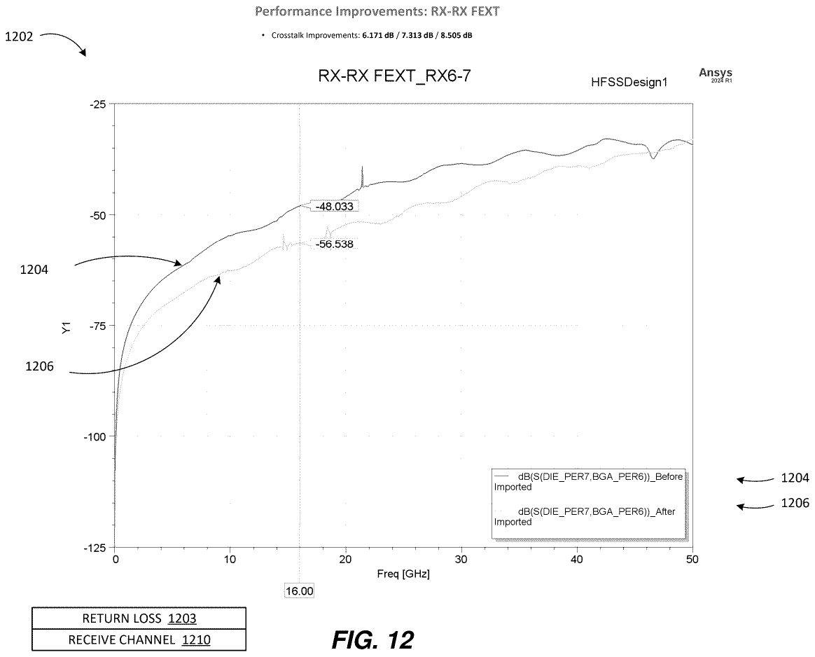

FIG. 12 illustrates an example of a receiver-receiver return loss graph 1202 (RX-RX return loss graph 1202) for an embodiment of the electronic system 100. The return loss graph 1202 shows return loss 1203 for an electrical signal loss in decibels over a range of frequencies for a receive channel 1210.

The RX-TX return loss graph 1202 show the performance of a sixth receiver lane and a seventh receiver lane. The RX-RX return loss graph 1202 can show the amount of signal power reflected back to the source along an electrical element. A higher value of the return loss 1203 shows lower reflection and better signal and power transmission. The return loss 1203 can be expressed as the logarithmic ratio of the power reflected back along the electrical element.

In some embodiments, the return loss graph 1102 can show the return loss 1103 for different configurations. The return loss graph 1102 can show an optimized return loss at approximately 16 GHz with the return loss at approximately 8.505 dB.

The return loss graph 1202 shows separate curves for different configurations. For example, the first curve 1204 can represent the return loss of a line from die side PER7 to a BGA side PER6 in a before configuration.. The second curve 1206 can represent the return loss of a line from the die side PER7 to the BGA side PER6.

In some embodiments, the first curve 1204, such as a before curve, can have a value of −48.033 at 16 GHz. The second curve 1206, such as an after curve, can have a value of 56.538 at 16 GHz. Here, the crosstalk improvement is approximately 8.5 dB. In still other embodiments, the crosstalk improvement can be 6.171 dB or 7.313 dB.

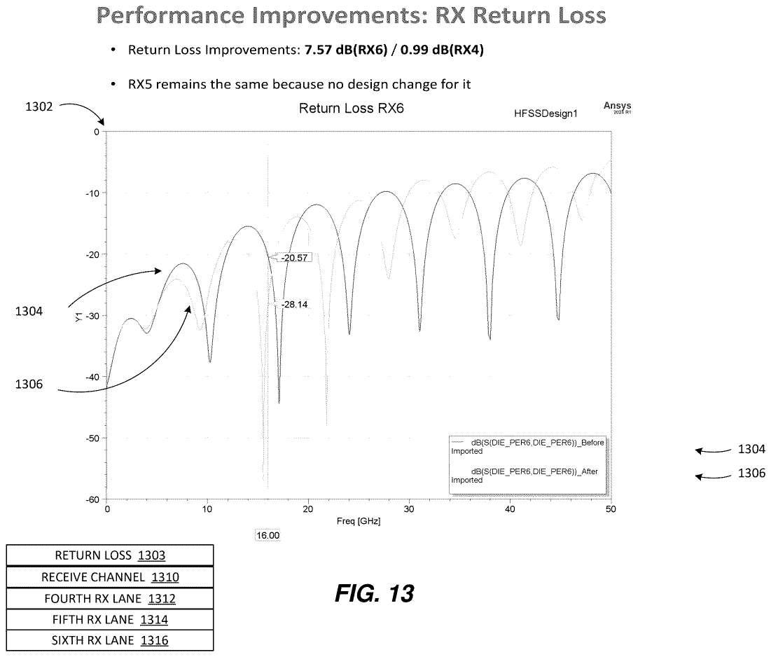

FIG. 13 illustrates an example of a receiver return loss graph 1302 (RX-RX return loss graph 1302) for an embodiment of the electronic system 100. The return loss graph 1302 shows return loss 1303 for an electrical signal loss in decibels over a range of frequencies for a receive channel 1310.

The RX-TX return loss graph 1302 show the performance of a sixth receiver lane 1416 in before and after configurations. The RX-RX return loss graph 1302 can show the amount of signal power reflected back to the source along an electrical element. A higher value of the return loss 1303 shows lower reflection and better signal and power transmission. The return loss 1303 can be expressed as the logarithmic ratio of the power reflected back along the electrical element.

In some embodiments, the return loss graph 1302 can show the return loss 1303 for different configurations. The return loss graph 1302 can show an optimized return loss at approximately 16 GHz with the return loss at approximately 7.57 dB.

The return loss graph 1302 shows separate curves for different configurations. For example, the first curve 1304 can represent the return loss of a line from die side PER6 in a before configuration. The second curve 1306 can represent the return loss of a line from the die side PER7 to the BGA side PER6.

In some embodiments, the first curve 1304, such as a before curve, can have a value of −20.57 at 16 GHz. The second curve 1306, such as an after curve, can have a value of 28.14 at 16 GHz. Thus, the improvement is approximately −7.57 dB for the sixth receiver lane and 0.99 dB for the fourth receiver lane. In this configuration the fifth receive lane 1314 is not modified.

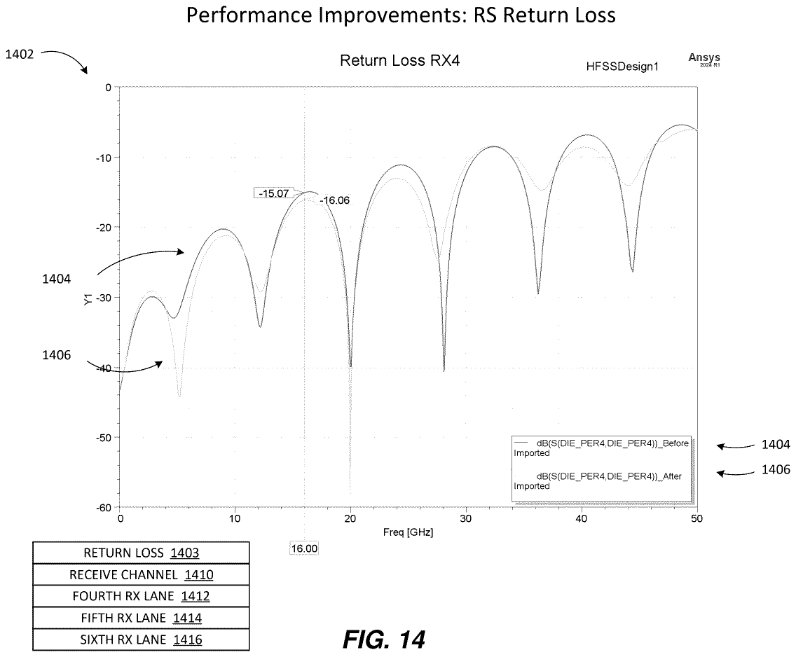

FIG. 14 illustrates an example of a receiver return loss graph 1402 (RS return loss graph 1402) for an embodiment of the electronic system 100. The return loss graph 1402 shows return loss for an electrical signal loss in decibels over a range of frequencies for a fourth receive lane 1412.

The RX return loss graph 1402 show the performance of a sixth receiver lane in before and after configurations. The RX return loss graph 1402 can show the amount of signal power reflected back to the source along an electrical element. A higher value of the return loss 1403 shows lower reflection and better signal and power transmission. The return loss 1403 can be expressed as the logarithmic ratio of the power reflected back along the electrical element.

In some embodiments, the return loss graph 1402 can show the return loss 1403 for different configurations. The return loss graph 1402 can show an optimized return loss at approximately 16 GHz with the return loss at approximately 0.99 dB.

The return loss graph 1402 shows separate curves for different configurations. For example, the first curve 1404 can represent the return loss of a line from die side PER4 in a before configuration. The second curve 1406 can represent the return loss of a line from the die side PER4 to the BGA side PER4.

In some embodiments, the first curve 1404, such as a before curve, can have a value of −15.07 at 16 GHz. The second curve 1406, such as an after curve, can have a value of 16.06 at 16 GHz. Thus, the improvement is approximately −0.99 dB for the fourth receiver lane 1412.

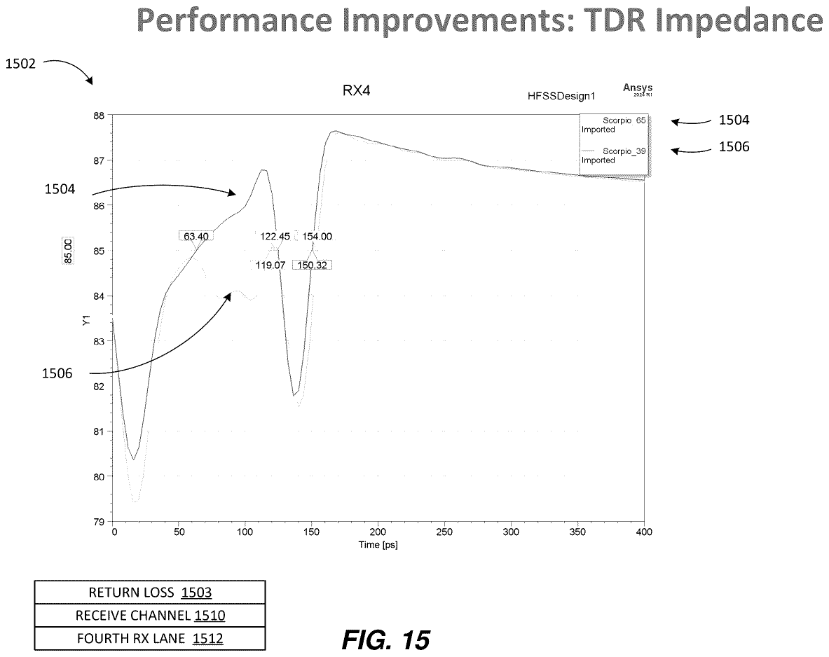

FIG. 15 illustrates an example of a time domain reflectometer impedance graph 1502 (TDR impedance graph 1502) for an embodiment of the electronic system 100. The return loss graph 1502 shows return loss for an electrical signal loss in decibels over a range of frequencies for the fourth receive lane 1512.

The TDR impedance graph 1502show the performance of the fourth receiver lane 1512 in two different configurations, Scorpio_65 and Scorpio_39. The TDR impedance graph 1502 can show the amount of signal power reflected back to the source along an electrical element. A higher value of the return loss 1503 shows lower reflection and better signal and power transmission. The return loss 1503 can be expressed as the logarithmic ratio of the power reflected back along the electrical element.

The TDR impedance graph 1502 shows separate curves for different configurations. For example, the first curve 1504 can represent the TDR impedance of the fourth receiver lane 1510 in the Scorpio_39 configuration. The second curve 1506 can represent the TDR impedance of the fourth receiver lane in the Scorpio_65 configuration.

In some embodiments, the first curve 1504, such as the Scorpio_39 configuration, can intersect the 85 ohm line at 119.07 picoseconds (ps), 122.45 ps, and 154 ps. The second curve 1506, such as the Scorpio_65 curve, can intersect the 85 ohm line at 63.40 ps, 123 ps, and 150.32 ps. Thus, the graph shows improvement in TDR impedance for the fourth receiver lane 1512.

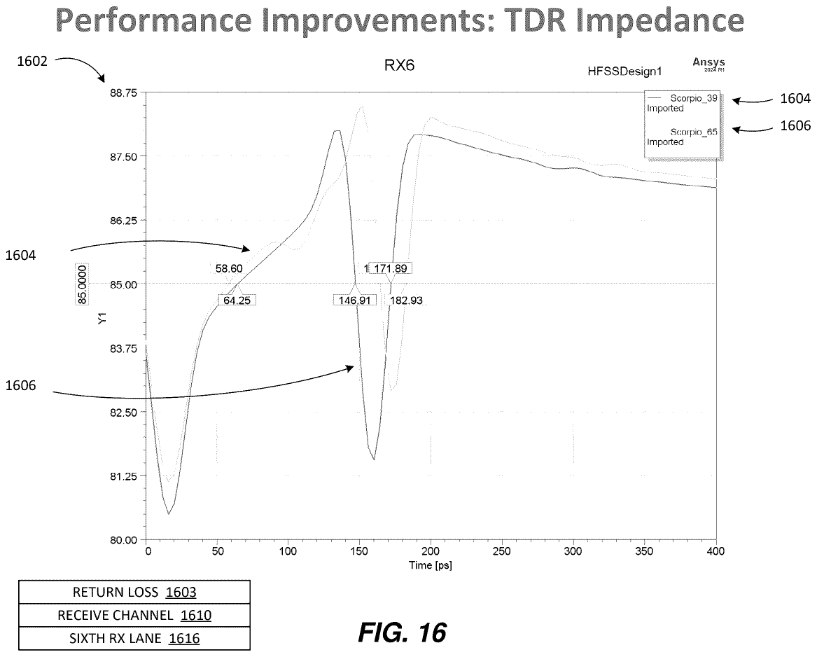

FIG. 16 illustrates an example of a time domain reflectometer impedance graph 1602 (TDR impedance graph 1602) for an embodiment of the electronic system 100. The return loss graph 1602 shows return loss 1603 for an electrical signal loss in decibels over a range of frequencies for the sixth receive lane 1616.

The TDR impedance graph 1602show the performance of a sixth receiver lane 1616 in before and after configurations. The TDR impedance graph 1602 can show the amount of signal power reflected back to the source along an electrical element. A higher value of the return loss 1603 shows lower reflection and better signal and power transmission. The return loss 1603 can be expressed as the logarithmic ratio of the power reflected back along the electrical element.

The TDR impedance graph 1602 shows separate curves for different configurations. For example, the first curve 1604 can represent the TDR impedance of the sixth receiver lane 1616 in the Scorpio_39 configuration. The second curve 1606 can represent the TDR impedance of the sixth receiver lane 1616 in the Scorpio_65 configuration.

In some embodiments, the first curve 1604, such as a Scorpio_39 curve, can intersect the 85 ohm line at 64.25 ps, 146.91 ps, and 171.89 ps. The second curve 1606, such as the Scorpio_65 curve, can intersect the 85 ohm line at 58.60 ps, 165 ps, and 182.93 ps. Thus, the graph shows improvement in TDR impedance for the sixth receiver lane 1616.

### 4.0. Functional Overview

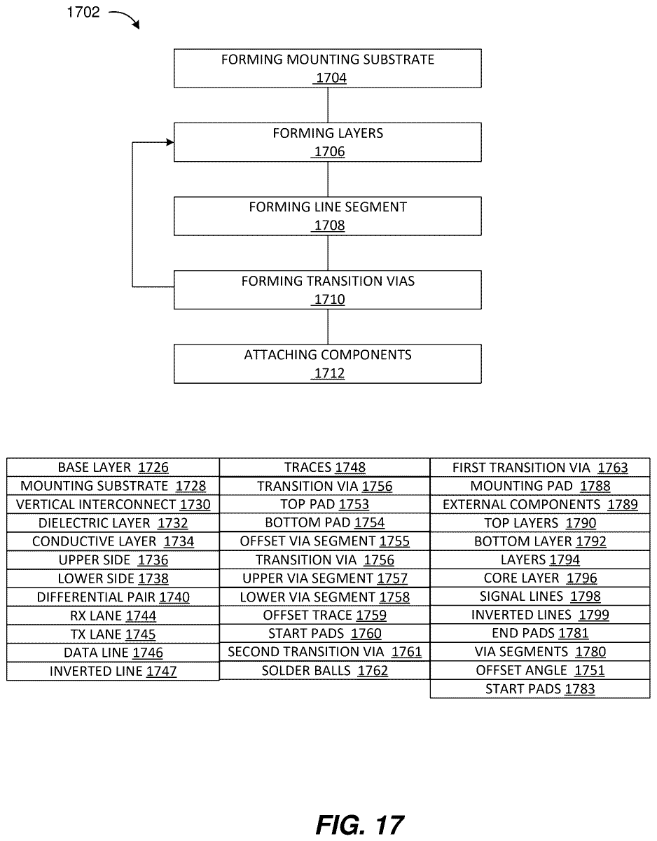

FIG. 17 illustrates an example of a manufacturing process flow 1702 for the electronic system 100 in an embodiment. The manufacturing process flow 1702 can describe the steps and process for manufacturing the mounting substrate 1728.

The manufacturing process flow 1702 can include a variety of operations. In an illustrative embodiment, the manufacturing process flow 1702 can include a initialize step 1704, a forming layer step 1706, a forming trace segments step 1708, a forming transition via step 1710, and an attach components step 1712.

In the initialize step 1704, the initial portion of the mounting substrate 1728 can be formed by procuring or forming at least a base layer 1726, such as a core layer 1796 of the mounting substrate 1728. The core layer 1796 can have at least two portions, a dielectric layer 1792 which can provide electrical insulation and mechanical structural stability and a conductive layer 1734 directly over the dielectric layer 1792.

In some embodiments, the base layer 1726 can have conductive layers on an upper side 1736 and a lower side 1738, such as an upper conductive layer and a lower conductive layer. The outer layers of the mounting substrate 1728 can be formed on opposite sides of the base layer 1726, such as upper and lower sides.

In other embodiments, such as coreless substrates embodiments, the base layer 1726 can have a single dielectric layer and an upper conductive layer. Additional outer layers can be formed over the base layer 1726.

The dielectric layer 1732 can be formed from a variety of materials, such as fiberglass, resin, or other similar materials. The conductive layer 1734 can be formed from metal or metal alloys including copper, silver, gold, or other similar conductive materials. The layers 1794 of the mounting substrate 1728 provide the basis for forming traces 1748 that support the functionality of the electronic system 100.

In the forming layers step 1706, additional layers of the mounting substrate 1728 can be formed. Starting with the core layer 1796, additional layers 1794 can be added on one or both sides of the core layer 1796. Once the dielectric layer 1732 has been formed, conductive elements can be formed on the dielectric layer 1732 the traces 1748 of the circuitry of the mounting substrate 1728 can be formed on the dielectric layer 1732.

In the forming line segment step 1708, the conductive elements can be formed on the dielectric layer 1732. The conductive element can include the traces 1748, the mounting pads 1788, the vertical interconnects 1730, and other similar elements configured to transfer signal information across the different layers of the mounting substrate 1728.

In some embodiments, the conductive elements can include the traces 1748 forming the differential pairs 1740. The mounting substrate 1728 can be configured to include a receiving lane 1744 and a transmission lane 1745 for transferring the data signals. The differential pair 1740 can have a data line 1746 and an inverted line 1747. The data line 1746 can carry a primary data signal while the inverted lines 1747 can carry a polarity inverted version of the primary data signal.

The differential pair 1740 can extend from a start point on a BGA side 1741 to an end point on a die side 1743. The path of the differential pair 1740 can traverse a transition via 1756. The position of the transition via 1756 can reduce the electromagnetic interference and lower the impedance of the differential pair 1740.

In the transition vias step 1710, the transition vias 1756 can be formed and coupled to the traces 1748 of the layer 1794. The traces 1748 can include the signal lines 1798 and the inverted lines 1799, as well as the structures of the transition vias 1756. Because of the related nature of the traces and the vias, the ordering and interleaving of the three steps can be repeated as necessary to form the conductive structures.

In some other embodiments, the vertical interconnects 1730 can be formed in a near adjacent area of the mounting substrate 1728. The top layer 1790 of the mounting substrate 1728 can be configured in a checkerboard layout and the vertical interconnects 1730 can be positioned to be offset from both a start pad 1783 and an end pad 1781, such as mounting pads 1788.

The vertical interconnect 1730 can be a transition via 1756. The transition via 1756 can be a structure having a multi-part via having two or more via segments 1780 that are horizontally offset from one another.

The transition vias 1756 can include several elements. The transition via 1756 can have a top pad 1753, a bottom pad 1754, an upper via segment 1757, an offset via segment 1755, an offset trace 1759, and a lower via segment 1758.

In some embodiments, the transition via 1756 can be positioned between the start point and the end point and configured to maximize the distance between the two points and the transition via 1756. In one configuration, the transition via 1756 is positioned in the middle of the differential pair 1740. In another configuration, the transition via 1756 is positioned between 40% and 60% of the length of the differential pair 1740. Other configurations can be used with the transition via 1756 positioned along the differential pair 1740. The transition vias 1756 can include a first transition via 1763 and a second transition via 1761.

The transition via 1756 can be configured to carry both lines of the differential pair 1740, the data line 1746 and the inverted line 1747. In some embodiments, the upper via segment 1757 of the data line 1746 can be positioned directly away from the upper via segment 1757 of the inverted line 1747. In still other embodiments, the upper via segment 1757 of the data line 1746 can be positioned away from the upper via segment 1757 of the inverted line 1747 by an offset angle 1751 in the range of −60 degrees and 60 degrees. can be offset from the upper via segment 1757 of the inverted line 1747.

In another embodiment, the upper via segment 1757 of one of the lines can be offset horizontally by the offset trace 1759. The length of the offset trace 1759 can be configured to reduce the impedance of the transition via 1756.

In some embodiments, the transition vias 1756 can be formed in a variety of ways. For example, the hole of the body of the transition vias 1756 can be formed by etching, drilling, sawing, laser drilling, chemical etching, photoetching, or other similar techniques. Afterward, the hole formed for the transition vias 1756 can be plated or filled with conductive material to form the conductor of the transition vias 1756.

The traces 1748 can be formed in a variety of ways. In some embodiments, the traces 1748 formed on the layers 1794 of the mounting substrate 1728 can be formed by plating, photoetching, photolithography, chemical vapor deposition, grinding, cutting, and other similar techniques.

In some embodiments, the control flow can pass back to the forming layers step 1706. However, if further layers are not required, the control flow can pass to the next step.

In the attaching components step 1712, electronic components 1782 can be attached to the mounting substrate 1728 using mounting pads 1788 and solder balls 1762. In some embodiments, the electronic components 1782 can be attached to both the top layer 1790 and the bottom layer 1792 of the mounting substrate 1728.

Other examples of these and other embodiments are found throughout this disclosure.

### 5.0. Example Embodiments

Examples of some embodiments are represented, without limitation, in the following clauses and use cases:

A method of manufacture of an electronic system comprising forming a portion of a mounting substrate having at least a core layer, forming a differential pair trace structure having a signal line and an inverted line, the inverted line carrying an inverted signal of the signal line, forming a signal start pad on a top layer of the mounting substrate, forming signal end pad on a bottom layer of the mounting substrate, forming a first transition via between a signal start pad on the top layer of the mounting substrate and a signal end pad on the bottom layer of the mounting substrate, the forming a second transition via between an inverted signal start pad and an inverted signal end pad, and attaching electronic components to the signal start pad and the signal end pad.

In an embodiment, the method wherein forming the first transition via includes forming the first transition via having an upper via segment electrically coupled to a lower via segment with an offset trace.

In an embodiment, the method wherein forming the first transition via includes forming the first transition via having an upper via segment offset from a lower via segment by an offset distance.

In an embodiment, the method wherein forming the first transition via includes forming the signal start pad on a top layer of the mounting substrate electrically coupled to an upper via segment with a loop back trace.

In an embodiment, the method wherein forming the first transition via includes forming the first transition via having a first upper via segment coupled to a first lower via segment with an offset trace, and forming the second transition via having a second upper via segment coupled to a second lower segment, the second lower via segment offset from the second upper via segment in a direction away from the first lower via segment.

In an embodiment, the method wherein forming the first transition via includes forming the first transition via having a first upper via segment coupled to a first lower via segment with a first offset trace, and forming the second transition via having a second upper via segment coupled to a second lower segment with a second offset trace, the first offset trace aligned with the same direction as the second offset trace.

In an embodiment, the method wherein forming the first transition via includes forming the first transition via having a first upper via segment coupled to a first lower via segment with a first offset trace, and forming the second transition via having a second upper via segment coupled to a second lower segment with a second offset trace, the first upper via segment and the second upper via segment between the first lower via segment and the second lower via segment.

In an embodiment, the method wherein forming the first transition via includes forming the first transition via having a first upper via segment electrically coupled to a first lower via segment with a first offset trace, the first upper via segment longer than the first lower via segment, and forming the second transition via having a second upper via segment coupled to a second lower segment with a second offset trace, the second upper via segment longer than the first lower via segment.

In an embodiment, the method wherein forming the first transition via includes forming the first transition via having a first upper via segment electrically coupled to a first lower via segment with a first offset trace, and forming the second transition via having a second upper via segment coupled to a second lower segment with a second offset trace, the first offset trace aligned in the same direction as the second offset trace.

In an embodiment, the method wherein forming the first transition via includes forming the first transition via having a first upper via segment electrically coupled to a first lower via segment with a first offset trace, the first upper via segment positioned more than 20% of the distance between the signal start pad and the signal end pad away from the signal start pad.

An electronic system comprises a mounting substrate having at least a core layer, a differential pair trace structure having a signal line and an inverted line both on the mounting substrate, the inverted line carrying an inverted signal of the signal line, the differential pair trace structure configured to electrically couple to electronic components, a signal start pad on a top layer of the mounting substrate, a signal end pad on a bottom layer of the mounting substrate, a first transition via positioned between the signal start pad on the top layer of the mounting substrate and a signal end pad on the bottom layer of the mounting substrate, the first transition via electrically coupled to the signal line of the differential pair trace structure, a second transition via positioned between the inverted signal start pad and an inverted signal end pad on the bottom side of the mounting substrate, the second transition via electrically coupled to the inverted line of the differential pair trace structure, and electronic components to the signal start pad and signal end pad.

In an embodiment, the system further comprises the first transition via having an upper via segment electrically coupled to a lower via segment with an offset trace.

In an embodiment, the system further comprises the first transition via having an upper via segment offset from a lower via segment by an offset distance.

In an embodiment, the system further comprises the signal start pad on a top layer of the mounting substrate and electrically coupled to an upper via segment with a loop back trace.

In an embodiment, the system further comprises the first transition via having a first upper via segment coupled to a first lower via segment with an offset trace, and the second transition via having a second upper via segment coupled to a second lower segment, the second lower via segment offset from the second upper via segment in a direction away from the first lower via segment.

In an embodiment, the system further comprises the first transition via having a first upper via segment coupled to a first lower via segment with a first offset trace, and the second transition via having a second upper via segment coupled to a second lower segment with a second offset trace, the first offset trace aligned with the same direction as the second offset trace.

In an embodiment, the system further comprises the first transition via having a first upper via segment coupled to a first lower via segment with a first offset trace, and the second transition via having a second upper via segment coupled to a second lower segment with a second offset trace, the first upper via segment and the second upper via segment between the first lower via segment and the second lower via segment.

In an embodiment, the system further comprises the first transition via having a first upper via segment electrically coupled to a first lower via segment with a first offset trace, the first upper via segment longer than the first lower via segment, and the second transition via having a second upper via segment coupled to a second lower segment with a second offset trace, the second upper via segment longer than the first lower via segment.

In an embodiment, the system further comprises the first transition via having a first upper via segment electrically coupled to a first lower via segment with a first offset trace, and the second transition via having a second upper via segment coupled to a second lower segment with a second offset trace, the first offset trace aligned in the same direction as the second offset trace.

In an embodiment, the system further comprises the first transition via having a first upper via segment electrically coupled to a first lower via segment with a first offset trace, the first upper via segment positioned more than 20% of the distance between the signal start pad and the signal end pad away from the signal start pad.

### 6.0. Extensions and Alternatives

As used herein, the terms “first,” “second,” “certain,” and “particular” are used as naming conventions to distinguish queries, plans, representations, steps, objects, devices, or other items from each other, so that these items may be referenced after they have been introduced. Unless otherwise specified herein, the use of these terms does not imply an ordering, timing, or any other characteristic of the referenced items.

The term “directly on” can indicate direct contact with no intervening elements. The term “directly beneath” can indicate an element is on a lower level but within the perimeter of another element.

In the drawings, the various components are depicted as being coupled to various other components by arrows. These arrows illustrate only certain examples of current flows between or through the components. Neither the direction of the arrows nor the lack of arrow lines between certain components should be interpreted as indicating the existence or absence of a flow between the certain components themselves.

In the specification, embodiments of the invention have been described with reference to numerous specific details that may vary from implementation to implementation. Thus, the sole and exclusive indicator of what is the invention and is intended by the applicants to be the invention, is the set of claims that issue from this application, in the specific form in which such claims issue, including any subsequent correction. In this regard, although specific claim dependencies are set out in the claims of this application, it is to be noted that the features of the dependent claims of this application may be combined as appropriate with the features of other dependent claims and with the features of the independent claims of this system, and not merely according to the specific dependencies recited in the set of claims. Moreover, although separate embodiments are discussed herein, any combination of embodiments and/or partial embodiments discussed herein may be combined to form further embodiments.

Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

It is understood that the system functionality can be described using terms like module, unit, system, subsystem, pod, and component that represent devices that can be implemented using different combinations of mechanical and electronic elements. The systems and devices can include electric subsystems, mechanical subsystems, and other physical elements to operate and control the system. These elements can include computing elements that can execute the firmware and software of the system to control mechanical features of the system. In addition, the mechanical elements of the system can operate with or without control mechanisms in regular operation.

1. A method of manufacture of an electronic system comprising:
forming a portion of a mounting substrate having at least a core layer;
forming a differential pair trace structure having a signal line and an inverted line, the inverted line carrying an inverted signal of the signal line,
forming a signal start pad on a top layer of the mounting substrate;
forming a signal end pad on a bottom layer of the mounting substrate;
forming a first transition via between the signal start pad on the top layer of the mounting substrate and the signal end pad on the bottom layer of the mounting substrate;
forming a second transition via between an inverted signal start pad and an inverted signal end pad; and
attaching electrical components to the signal start pad and the signal end pad.

2. The method of claim 1, wherein forming the first transition via includes forming the first transition via having an upper via segment electrically coupled to a lower via segment with an offset trace.

3. The method of claim 1, wherein forming the first transition via includes forming the first transition via having an upper via segment offset from a lower via segment by an offset distance.

4. The method of claim 1, wherein forming the first transition via includes forming the signal start pad on a top layer of the mounting substrate electrically coupled to an upper via segment with a loop back trace.

5. The method of claim 1, wherein forming the first transition via includes:
forming the first transition via having a first upper via segment coupled to a first lower via segment with an offset trace; and
forming the second transition via having a second upper via segment coupled to a second lower segment, the second lower via segment offset from the second upper via segment in a direction away from the first lower via segment.

6. The method of claim 1, wherein forming the first transition via includes:
forming the first transition via having a first upper via segment coupled to a first lower via segment with a first offset trace; and
forming the second transition via having a second upper via segment coupled to a second lower segment with a second offset trace, the first offset trace aligned with the same direction as the second offset trace.

7. The method of claim 1, wherein forming the first transition via includes:
forming the first transition via having a first upper via segment coupled to a first lower via segment with a first offset trace; and
forming the second transition via having a second upper via segment coupled to a second lower segment with a second offset trace, the first upper via segment and the second upper via segment between the first lower via segment and the second lower via segment.

8. The method of claim 1, wherein forming the first transition via includes:
forming the first transition via having a first upper via segment electrically coupled to a first lower via segment with a first offset trace, the first upper via segment longer than the first lower via segment; and
forming the second transition via having a second upper via segment coupled to a second lower segment with a second offset trace, the second upper via segment longer than the first lower via segment.

9. The method of claim 1, wherein forming the first transition via includes:
forming the first transition via having a first upper via segment electrically coupled to a first lower via segment with a first offset trace; and
forming the second transition via having a second upper via segment coupled to a second lower segment with a second offset trace, the first offset trace aligned in the same direction as the second offset trace.

10. The method of claim 1, wherein forming the first transition via includes:
forming the first transition via having a first upper via segment electrically coupled to a first lower via segment with a first offset trace, the first upper via segment positioned more than 10% of the distance between the signal start pad and the signal end pad away from the signal start pad.

11. An electronic system comprising:
a mounting substrate having at least a core layer;
a differential pair trace structure having a signal line and an inverted line both on the mounting substrate, the inverted line carrying an inverted signal of the signal line, the differential pair trace structure configured to electrically couple to electronic components;
a signal start pad on a top layer of the mounting substrate;
a signal end pad on a bottom layer of the mounting substrate;
a first transition via positioned between the signal start pad on the top layer of the mounting substrate and a signal end pad on the bottom layer of the mounting substrate, the first transition via electrically coupled to the signal line of the differential pair trace structure;
a second transition via positioned between the inverted signal start pad and an inverted signal end pad on the bottom side of the mounting substrate, the second transition via electrically coupled to the inverted line of the differential pair trace structure; and
electronic components attached to the signal start pad and signal end pad.

12. The system of claim 11, further comprising the first transition via having an upper via segment electrically coupled to a lower via segment with an offset trace.

13. The system of claim 11, further comprising the first transition via having an upper via segment offset from a lower via segment by an offset distance.

14. The system of claim 11, further comprising the signal start pad on a top layer of the mounting substrate and electrically coupled to an upper via segment with a loop back trace.

15. The system of claim 11, further comprising:
the first transition via having a first upper via segment coupled to a first lower via segment with an offset trace; and
the second transition via having a second upper via segment coupled to a second lower segment, the second lower via segment offset from the second upper via segment in a direction away from the first lower via segment.

16. The system of claim 11, further comprising:
the first transition via having a first upper via segment coupled to a first lower via segment with a first offset trace; and
the second transition via having a second upper via segment coupled to a second lower segment with a second offset trace, the first offset trace aligned with the same direction as the second offset trace.

17. The system of claim 11, further comprising:
the first transition via having a first upper via segment coupled to a first lower via segment with a first offset trace; and
the second transition via having a second upper via segment coupled to a second lower segment with a second offset trace, the first upper via segment and the second upper via segment between the first lower via segment and the second lower via segment.

18. The method of claim 11, further comprising:
the first transition via having a first upper via segment electrically coupled to a first lower via segment with a first offset trace, the first upper via segment longer than the first lower via segment; and
the second transition via having a second upper via segment coupled to a second lower segment with a second offset trace, the second upper via segment longer than the first lower via segment.

19. The system of claim 11, further comprising:
the first transition via having a first upper via segment electrically coupled to a first lower via segment with a first offset trace; and
the second transition via having a second upper via segment coupled to a second lower segment with a second offset trace, the first offset trace aligned in the same direction as the second offset trace.

20. The system of claim 11, further comprising the first transition via having a first upper via segment electrically coupled to a first lower via segment with a first offset trace, the first upper via segment positioned more than 20% of the distance between the signal start pad and the signal end pad away from the signal start pad.
